(19) United States
(12) Patent Application Publication
(10) Pub. No.: US 2003/0012712 A1
(43) Pub. Date: Jan. 16, 2003

(54) Apparatus for whole wafer processing

(75) Inventor: Michael C. Norris, Santa Clara, CA (US)

Correspondence Address: THOMASON, MOSER & PATTERSON, L.L.P., Suite 1500, 3040 Post Oak Blvd., Houston, TX, 77056, US

(73) Assignee: Perlegen Sciences

(21) Appl. No.: 09/907,015

(22) Filed: Jul. 16, 2001

(51) Int. Cl. H01L 21/00; B01J 2/00

(52) U.S. Cl. 422/236; 438/1; 438/745

(57) ABSTRACT

Generally, a method and apparatus for processing whole wafers comprising is provided. In one embodiment, an apparatus for processing whole wafers includes a cassette, a plurality of flowcells disposed on the cassette, a fluidics station having at least one pump, at least one fluid source in communication with the pump and a cradle for receiving the cassette when coupled to the fluidic station. The flowcells generally are adapted to retain at least one whole wafer and include an inlet port and an outlet port. The pump of the fluidic station is coupled to one or more inlet ports of the flowcells disposed in the cassette. The apparatus enables multiple whole wafers to be simultaneously processed while providing flexibility of accommodate different configurations of flowcells.

### BACKGROUND OF THE DISCLOSURE

1. Field of the Invention

Embodiments of the invention generally relate to an apparatus and concomitant method for carrying out hybridization of a target nucleic acid to an array of nucleic acid probes positioned on a substrate, such as a wafer.

2. Description of the Background Art

Techniques for forming sequences on a substrate, such as a wafer, are known. For example, the sequences may be formed according to the pioneering techniques disclosed in U.S. Pat. No. 5,143,854, issued Sep. 1, 1992 to Pirrung et al., PCT WO 92/10092, published Jun. 25, 1992 by Fodor, et al., or U.S. Pat. No. 5,571,639, issued Nov. 5, 1996 to Hubbell, et al., all of which are hereby incorporated by reference in their entireties. The prepared substrates will have a wide range of applications. For example, the substrates may be used for understanding the structure-activity relationship between different materials or determining the relatedness of an unknown sample or target to the arrayed molecule. In one method of expression or profiling, known sequences are formed at known locations on the surface of a substrate. A solution containing one or more targets to be analyzed is applied to the surface of the substrate. The targets will bind or hybridize with only complementary sequences on the substrate.

The locations at which hybridization occurs can be detected with appropriate detection systems by labeling the targets with a fluorescent dye, radioactive isotope, enzyme, or other marker. Exemplary systems are described in previously incorporated U.S. Pat. No. 5,143,854 and U.S. patent application Ser. No. 08/143,312, which is hereby incorporated by reference in its entirety. Information regarding target sequences can be extracted from the data obtained by such detection systems.

By combining various available technologies, such as photolithography and fabrication techniques, substantial progress has been made in the fabrication and placement of diverse materials on a substrate. For example, thousands of different sequences may be fabricated on a single substrate of about 1.28 cm² in only a small fraction of the time required by conventional methods. Such improvements make these and larger substrates practical for use in various applications, such as biomedical research, clinical diagnostics, and other industrial markets, as well as the emerging field of genomics, which focuses on determining the relationship between genetic sequences and human physiology.

As commercialization of such substrates becomes widespread, apparatus and methods for producing such substrates with both high accuracy and increased throughput are in great demand. Therefore, a need exists for an improved method and apparatus for processing a wafer.

### SUMMARY OF THE INVENTION

In one aspect of the invention, an apparatus for processing a whole wafer is provided. In one embodiment, an apparatus for processing a whole wafer includes a cassette, a plurality of flowcells disposed on the cassette, a fluidics station having at least one pump, at least one fluid source in communication with the pump and a cradle for receiving the cassette when coupled to the fluidic station. The flowcells generally are adapted to retain at least one whole wafer and include an inlet port and an outlet port. The pump of the fluidic station is coupled to one or more inlet ports of the flowcells disposed in the cassette. The apparatus enables multiple whole wafers to be simultaneously processed while providing flexibility to accommodate different configurations of flowcells.

In another aspect of the invention, a method for processing a whole wafer is provided. In one embodiment, a method for processing a whole wafer includes simultaneously processing batches of whole wafers retained in a single removable cassette. In another embodiment, a method for processing a whole wafer includes circulating process fluids through one flowcell containing a whole wafer. In another embodiment, a method for processing a whole wafer includes adjusting an orientation between a cassette retaining multiple flowcells and a cradle to accommodate a first configuration of flowcells processed in a first batch and a second configuration of flowcells processed in a second batch.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1A is an exploded view of one embodiment of a flowcell;

FIG. 1B is an elevation of a back side of the flowcell of FIG. 1A;

FIG. 1C is a side of the flowcell of FIG. 1B;

FIG. 1D is another side of the flowcell of FIG. 1B;

FIG. 1E is a sectional view of of the flowcell of FIG. 1D taken along section lines 1E-1E;

FIG. 2A is an exploded view of another embodiment of a flowcell;

FIG. 2B is an elevation of a back side of the flowcell of FIG. 2A;

FIG. 3 depicts another embodiment of a flowcell;

FIG. 4 is an exploded view of another embodiment of a flowcell;

FIG. 5 is depicts a sectional view of one embodiment of an inlet port of the flowcell of FIG. 4 taken along section line 5-5;

FIG. 6 is depicts perspective view of the flowcell of FIG. 4;

FIG. 7 is an exploded view of one embodiment of a flowcell cassette;

FIG. 8 is a perspective view one embodiment of a cassette adapter;

FIG. 9 is a perspective view one embodiment of a fluidic system

FIG. 10 is a perspective view one embodiment of a fluid delivery module;

FIG. 11 is a schematic of one embodiment of a fluid delivery module;

FIG. 12 is a schematic of another embodiment of a fluid delivery module;

FIG. 13 is one embodiment of a cradle;

FIG. 14 is another embodiment of a cradle;

FIG. 15 is a schematic of another embodiment of a fluid delivery module; and

FIG. 16 is one embodiment of a catch assembly.

To facilitate understanding, identical reference numerals have been used, wherever possible, to designate identical elements that are common to the figures.

### DETAILED DESCRIPTION

I. Introduction

Aspects of the present invention generally provide an apparatus for rapidly and efficiently carrying out repeated, controlled hybridization reactions with polymer arrays. Generally, the apparatuses described herein are referred to as fluidics stations. To accomplish the above, the fluidics stations described herein generally include a fluid delivery system for delivering a sample or wash solution to a hybridization reaction chamber or flowcell, a plurality of valves to select which solution is delivered to the flowcell and a process control system for operating each of these individual systems according to a preprogrammed operating profile.

The fluidics stations described herein are generally useful for processing hybridization arrays. For example, the fluidics stations may be used for staining a hybridization array, washing a hybridization array or a stained array, recovering a sample from a hybridization array, recovering stain from a stained array, hybridization reactions and the like. In some aspects, the polymer arrays are oligonucleotide arrays that include a plurality of different oligonucleotides coupled to a solid substrate in different known locations. Such polymer arrays have been previously described in the previously incorporated U.S. Pat. No. 5,143,854 and in published PCT Application Nos. WO 90/15070 and 92/10092. These pioneering arrays may be produced using mechanical or light directed synthesis methods that incorporate a combination of photolithographic methods and solid phase oligonucleotide synthesis methods. See Fodor et al., Science, 251:767-777 (1991), Pirrung et al., U.S. Pat. No. 5,143,854 (see also PCT Application No. WO 90/15070) and Fodor et al., PCT Publication No. WO 92/10092, all incorporated herein by reference in their entireties. These references disclose methods of forming vast arrays of peptides, oligonucleotides and other polymer sequences using, for example, light-directed synthesis techniques. Techniques for the synthesis of these arrays using mechanical synthesis strategies are described in PCT Publication No. 93/09668 and U.S. Pat. No. 5,384,261, each of which is incorporated herein by reference in its entirety.

Although generally described in terms of washing and staining arrays, it should be appreciated that a variety of processes, some of which discussed above, may be performed using the fluidics stations of the present invention.

II. Fluidics Station

A. Flowcell (Array Cartridge)

The flowcell generally includes a body having a reaction cavity disposed therein. The array or substrate is mounted over the cavity on the body such that the front side of the array substrate, i.e., the side upon which the array has been synthesized, is in fluid communication with the cavity. The bottom of the cavity may optionally include a light absorptive material, such as a glass filter or carbon dye, to prevent impinging light from being scattered or reflected during imaging by detection systems. This feature improves the signal-to-noise ratio of such detection systems by significantly reducing the potential imaging of undesired reflected light.

The flowcell also typically includes fluid inlets and fluid outlets for flowing fluids into and through the cavity. Optionally, a septum, plug, or other seal may be employed across the inlets and/or outlets to seal the fluids in the cavity. The flowcell also typically includes alignment structures, e.g., alignment pins, bores, and/or an asymmetrical shape to ensure correct insertion and/or alignment of the flowcell in the assembly devices, fluidics stations, and reader devices. One flowcell that may be adapted to benefit from the invention is described in U.S. Pat. No. 5,945,334, which issued on Aug. 31, 1999 to Besemer et al. and is hereby incorporated by reference in its entirety.

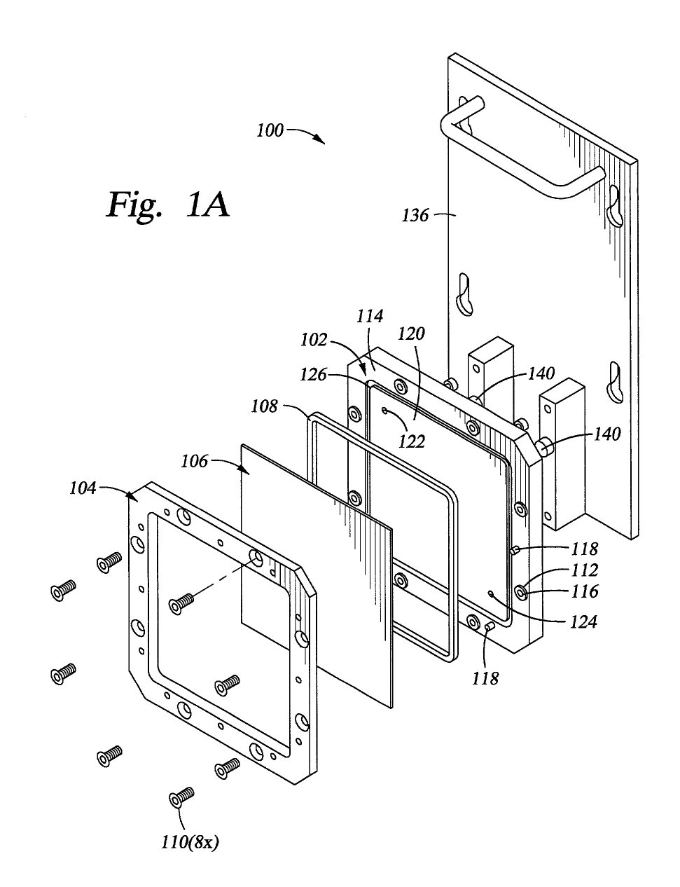

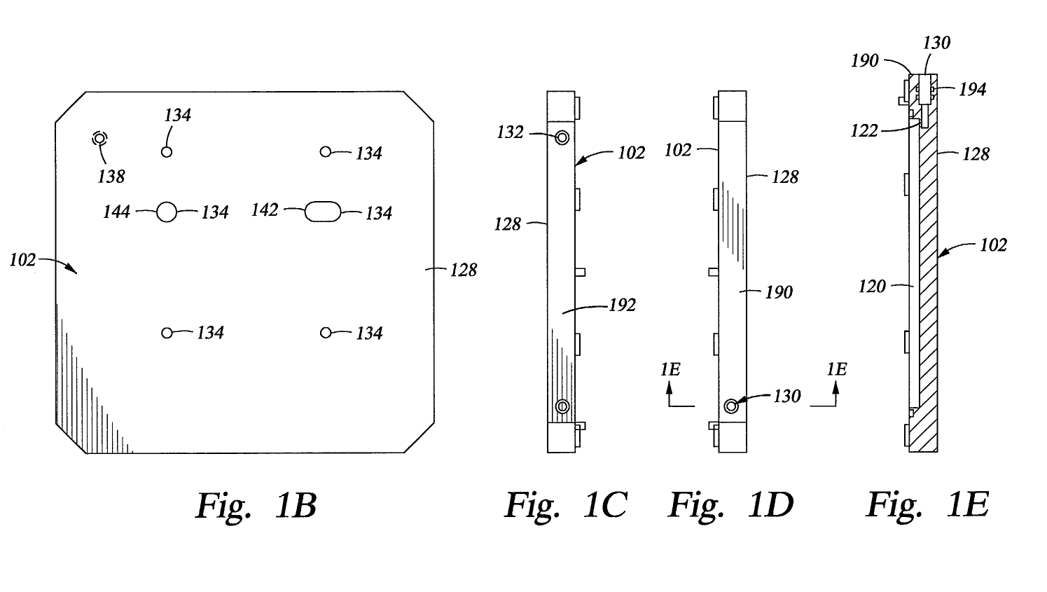

FIGS. 1A, 1B 1C, 1D and 1E respectively depict an exploded perspective view, a back elevation, a side view, another side view and a sectional view of one embodiment of an array cartridge or flowcell 100. The flowcell 100 generally includes a body 102 and a face plate 104. A whole wafer 106 is generally clamped between the body 102 and face plate 104 for processing. The wafer 106 is orientated so that probe arrays disposed thereon face the body 102 (i.e., only the side of the wafer 106 facing the body 102 containing the polymer array to be processed). Generally, the wafer 106 have a surface area of at least about 1 square inch and are about 0.027 thick. Typically, the wafer 106 is configured in a commercially available size, for example, having a surface of about 5 by 5 inches or about 1 by 3 inches, although other sizes may be utilized.

Generally, an elastomeric gasket 108 is disposed between the wafer 106 and body 102 to contain the various process and other fluids (stains, sample, buffer, etc.) between the wafer 106 and body 102 during processing. The body 102 and face plate 104 are held together by a releasable device, for example, adhesives, clips, quarter turn fasteners, snap fits or other fastening methods.

In the embodiment illustrated in FIGS. 1A and 1B, the face plate 104 is screwed to the body 102 by a plurality of mounting screws 110. The body 102 generally includes a number of bosses 112 extending from a front side 114 adjacent the face plate 104. Each boss 112 includes a threaded hole or threaded insert 116 that accepts one of the mounting screws 110. The height of each boss 112 relative the front side 114 is configured to maintain the body 102 and face plate 104 at a predetermined, spaced-apart relation when fastened to each other thus preventing damage to the wafer 106 by over tightening the screws 110. Additionally, the height of the boss 112 is selected to provide the proper compression of the gasket 108 to ensure good sealing between the wafer 106 and body 102. The height of the boss 112 is also selected to allow for a consistent volume of the reaction chamber or plenum defined by the wafer 106, the seal 108, and the front side 114 of the flowcell 102.

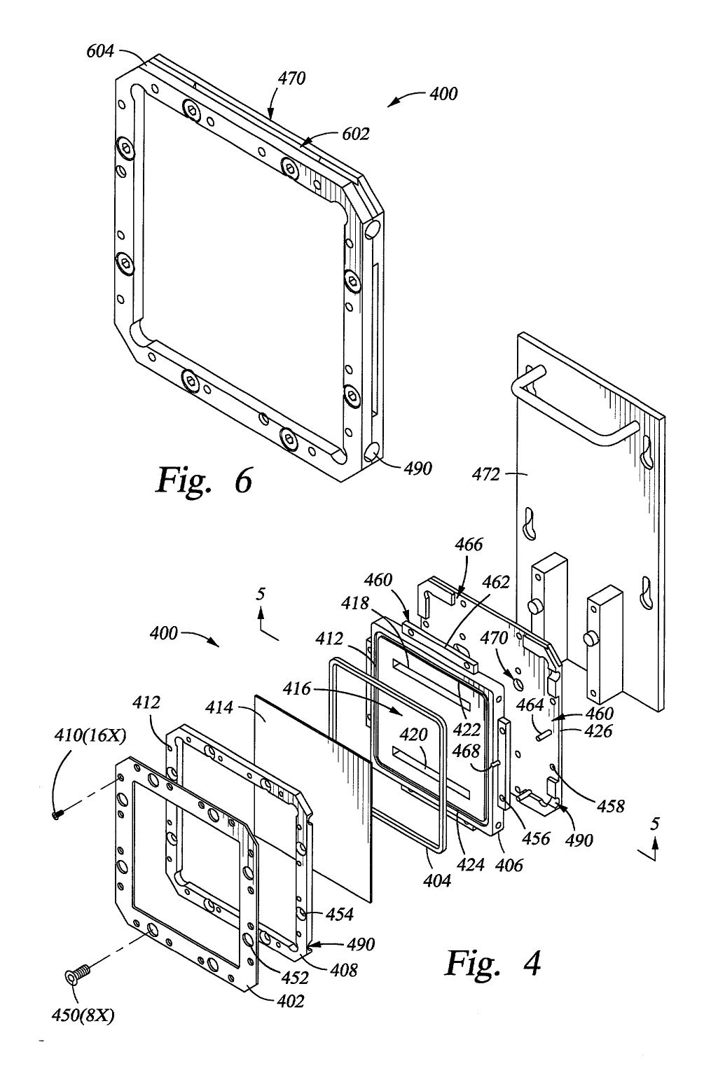

The body 102 may comprise any relatively rigid material, such as aluminum, stainless steel, quartz, ceramic, polymers, for example, acrylonitrile butadiene styrene (ABS) and others, rigid or reinforced polymer or similar suitable material. The body 102 may additionally be comprised of or coated with a material compatible with the fluids and compositions used in the flowcell 100, such as, for example polytetrafluoroethylene, acrylonitrile butadiene styrene, stainless steel and other materials. Alternatively, the body 102 may comprise a less rigid material when used in concert with a rigid backing plate as described below with reference to the flowcell shown in FIG. 4.

The face plate 104 may be fabricated from any relatively rigid material, such as aluminum, stainless steel, quartz, ceramic, rigid or reinforced polymer or similar suitable material. Typically, the face plate 104 includes a hollow center portion 146 that allows substantially all of the wafer 106 to be viewed through the face plate 104 after installation in the flowcell 100.

The gasket 108 is generally fabricated from a material compatible with the materials, reagents and other fluids utilized in the flowcell 100. Examples of some materials that may be utilized include elastomers, perflouinated elastomers, polytetrafluoroethylene, nitrile, silicone and the other process compatible materials. The gasket 108 may have various sectional profiles such as rectangular, round, flat or other shape and may be fabricated by various processes including die cutting or molding. Additionally, a portion of the gasket 108 may be disposed in a groove 126 formed in the body 102 to assist in maintaining the position of the gasket 108 during clamping of the wafer 106. Alternatively, the gasket 108 may be located in other manners.

A plurality of alignment pins 118 generally extends between the front side 114 of the body 102 facing the wafer 106 and face plate 104. The alignment pins 118 generally align the wafer 106 on the body 102 and may optionally extend beyond the height of the bosses 112 to additionally interface with and locate the face plate 104 to the body 102. Typically, the pins 118 project from the front side 114 of the body 102. Alternatively, the pins 118 may extend from the face plate 104.

A portion of the front side 114 of the body 102 disposed inwards of the gasket 108 defines a processing region 120. The processing region 120 may be formed in the front side 114 of the body 102 creating a plenum for fluids disposed between the body 102 and wafer 106. Optionally, the front side 114 may be substantially planar such that the plenum defining the processing region 120 is bounded by a portion of the gasket 108 maintains the body 102 and wafer 106 in a spaced-apart relation. Generally, the depth of the plenum (i.e., the distance between the body 102 and wafer 106) is between about 0.6 mm to about 7 mm to ensure adequate room for processing and fluid flow.

The processing region 120 generally includes at least one inlet 124 and outlet 122 that provide for entrance and egress of fluids to the plenum. The inlet 124 and outlet 122 are fluidly coupled to a respective inlet port 130 and outlet port 132 disposed respectively on a first side 190 and a second side 192 of the body 102 (see FIGS. 1C and 1D). Optionally, the inlet port 130 and/or the outlet port 132 may be disposed in the back side 128.

As depicted in FIG. 1E, the inlet port 130 is disposed through the body 102 and generally includes a threaded portion 194 to facilitate coupling a fitting (not shown) thereto. Generally, the fitting disposed in the inlet port 130 interfaces with the fluid delivery system described below. The fitting may be barb, flat bottom, luer, leak-tight or other fitting adapted to facilitate fluid transfer and/or retention (such as a check valve). The outlet port 132 is similarly configured.

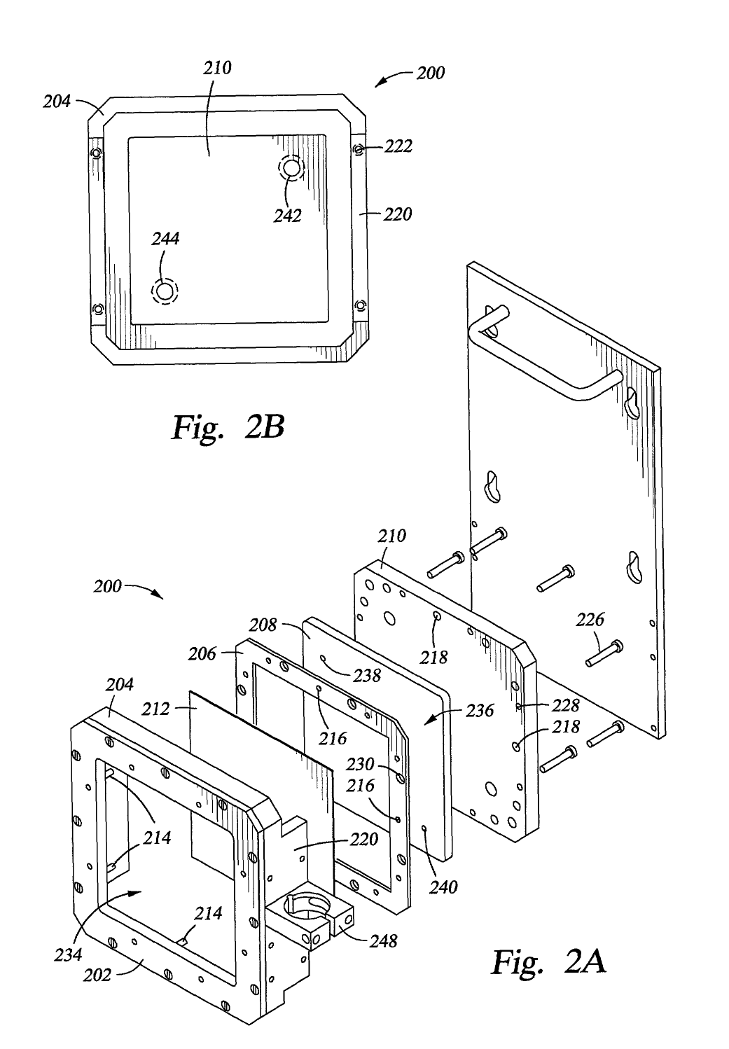

Typically, barbed fittings such as #10-32×1/16 barbs as sold by Value Plastics, Inc. are utilized. Optionally, as shown in FIG. 2A, 1/4×28TPI flat bottom fittings may be used. Other fittings commonly used in chromatography, such as those sold by Diba or Upchurch, may also used.

Typically, the inlet 124 and outlet 122 are disposed in a spaced-apart relation on the processing region 120, and preferably at opposite corners of the square area defined by the processing region 120. During processing, the processing region 120 is typically orientated so that the inlet 124 is vertically disposed under the outlet 122 to promote efficient fluid flow throughout the entire processing region 120 and ensure the optimal draining of the processing fluids with minimal mixing or cross-talk between fluids when switching from one fluid to another. As the processing region 120 and the gasket 108 are typically square or rectangular in form and orientated with their sides parallel with the edges of the flowcell 100, to achieve a vertical orientation between the inlet 124 and outlet 122, the flowcell 100 must be disposed at a 45 degree angle (relative the edge of the flowcell 100 or force creating cell drainage, such as a centrifuge or similar device). Accordingly, the processing region 120 may be disposed within the flowcell 100 in other angular orientations or defined by other geometry, and one skilled in the art would readily be able to orientate the inlet 124 and outlet 122 appropriately.

The back side 128 of the body 102 generally includes one or more locating features 134. The locating features 134 generally allow the flowcell 100 to be accurately interfaced with other objects such as a transfer plate 136. Typically, one or more threaded holes 138 are provided in the back side 128 of the body 102 to allow fasteners to secure the transfer plate 136 to the body 102. The transfer plate 136 can be used to interface the flowcell 100 with the scanner which has a stage with four screws that interface with the four “keyhole” slots in the transfer plate 136.

In one embodiment, the locating features 134 include a plurality of blind holes (shown as holes 142, 144) disposed in the backside 128. Mating features, such as dowel pins 140 partially projecting from the transfer plate 136, interface with the blind holes 142, 144 to align the flowcell 100 to the transfer plate 136. The locating features 134 may additionally or alternatively include features along the edges of the flowcell 100 (such as grooves, slots, pins, and other mating geometry), projecting members or other features or members utilized to locate the flowcell 100 relative to another object.

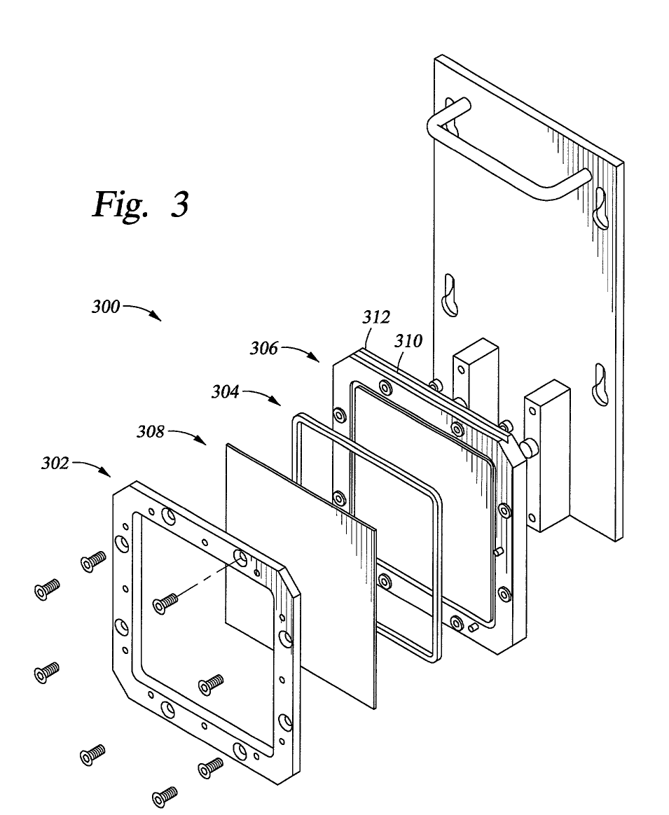

For example, FIG. 3 depicts an embodiment of a flowcell 300 having a face plate 302, gasket 304 and a body 306 configured to retain a wafer 308 in a fashion similar to the flowcell 100 described with reference to FIGS. 1A and 1B except wherein the body 306 includes a locating feature 134 such as a groove 310 disposed in at least one side 312 of the body 306. The groove 310 permits easier handling of the flowcell 300, are more suited for automation, and allow greater flexibility for interfacing the flowcell 300 with a variety of devices (i.e., fluidic stations, scanners, incubators and the like).

Returning to the embodiment shown in FIGS. 1A and 1B, the wafer 106 is depicted as having a square form, and to maximize the processing, the gasket 108, face plate 104 and processing region 120 are also in square form. Alternatively, mixed geometries may be utilized. Additionally, in embodiments not shown and readily devised by one skilled in the art following the disclosure herein, other wafer geometries, for example round or rectangular, may be used.

FIGS. 2A and 2B respectively depict an exploded perspective view and a back elevation of another embodiment of a flowcell 200. The flowcell 200 includes a face plate 202, a ring 204, a gasket 206, a backplate 208 and a clamp plate 210. A wafer 212 is generally clamped between the backplate 208 and face plate 202 for processing. The wafer 212 is orientated so that probe arrays disposed thereon face the backplate 208. Generally, an elastomeric gasket 206 is disposed between the wafer 212 and backplate 208 to contain the various process and other fluids (stains, sample, buffer, etc.) between the wafer 212 and backplate 208 during processing. The backplate 208 is generally clamped between the clamp plate 210 and face plate 202 by a releasable device, for example, screws, bolts, adhesives, clips, quarter turn fasteners, snap fits or other fastening devices.

In the embodiment illustrated in FIGS. 2A and 2B, the flowcell 200 is generally held together by a plurality of mounting screws 226. The screws 226 generally pass respectively through holes 228 disposed in the clamp plate 210 and holes 230 disposed in the gasket 206 and thread into a hole 232 disposed in the face plate 202. The backplate 208 is generally clamped between the gasket 206 and clamp plate 210. The backplate 208 is generally disposed inward of the screws 226 but may optionally include holes (not shown) for passing the screws 226 therethrough. In certain embodiments, the backplate 208 may optionally include a number of bosses (not shown) to prevent damage to the wafer 212 by over tightening the screws 226.

The face plate 202 generally includes a plurality of alignment pins 214 (three are shown in FIG. 2A) disposed between the plate 202 and the face plate 202. Typically, the pins 214 extend from the side of the plate 202 facing the wafer 212. The gasket 206 generally includes holes 216 which allow pins 214 to pass therethrough, thus aligning the gasket 206 and face plate 202. The ring 204 is fastened to the face plate 202 on the same side as the pins 214 and includes a pair of mounting tabs 220 extending therefrom. The tabs 220 are disposed in a spaced-apart relation that allows the backplate 208 and clamp plate 210 to be disposed therebetween while aligning the backplate 208 and clamp plate 210 with the face plate 202. The tabs 220 additionally include a plurality of threaded mounting holes 222 that allow the flowcell 200 to be secured to a transfer plate 224 or other device.

The ring 204 may additionally include an optional tube bracket 248. The tube bracket 248 facilitates holding a vial used to monitor and control the fluid pressure within the flowcell 200 when placed on a scanner (vial and scanner not shown). For example, when the flowcell 200 is disposed on the scanner, it is generally filled with fluid. Due to the density of fluid and the fact that the scanner mounts the flowcell 200 in a vertical orientation, the fluid behind the wafer 212 exerts pressure on the wafer 212. As the wafer 212 is thin, this pressure will cause deformation of the wafer 212, exceeding the maximum allowable by the scanner optics/focus control system. Now, in the system as it is used, one port of the flowcell 200 is capped off, and the other port is fluidly coupled to an open topped vial partially filled with solution. Since the fluid is static, the pressure applied to the wafer 212 by the fluid is a function of the free surface in this vial. The free surface marks the zero pressure point, and any fluid above it in the system is under a slight vacuum. That is, if the vial is filled such that the level in the vial was at the midpoint of the flowcell 200, the upper portion of the wafer would be pushed in by atmospheric pressure while the lower portion of the wafer would be pushed out by the fluid pressure. By raising or lowering the level of the fluid, the pressure on the wafer can be changed, thus changing the bowing of the wafer 212. The tube bracket 248 facilitates the mounting of the vial.

The face plate 202, backplate 208 and clamp plate 210 may be fabricated from any relatively rigid material, such as aluminum, stainless steel, quartz, ceramic, rigid or reinforced polymer or similar suitable material. The face plate 202 may be comprised of less rigid material in embodiments such as shown in FIGS. 2A and 2B where the clamp plate 210 reinforces the backplate. The backplate 208 and clamp plate 210 should additionally be comprised of or coated with a material compatible with the fluids and compositions used in the flowcell 200.

Typically, the face plate 202 includes a hollow center portion 234 that allows substantially all of the wafer 212 to be viewed through the face plate 202 after installation in the flowcell 200. The face plate 202 may optionally include locating features 134 similar to those discussed with reference to the flowcell 100 of FIGS. 1A and 1B.

The gasket 206 is generally fabricated from a material compatible with the materials, reagents and other fluids utilized in the flowcell 200. Examples of some materials that may be utilized include polytetrafluoroethylene, silicone and the like. The gasket 206 may have various sectional profiles such as rectangular, round or other geometries.

A portion of the backplate 208 disposed inwards of the gasket 206 defines a processing region 236. The processing region 236 may be recessed into the backplate 208 to create a plenum for fluids disposed between the backplate 208 and wafer 212. In the embodiment depicted in FIG. 2A, the processing region 236 is coplanar with the front side 214 such that the plenum is defined by the portion of the gasket 206 that maintains the backplate 208 and wafer 212 in a spaced-apart relation. As such, the height (e.g., thickness) of the gasket 206 may be selected to define the volume of the processing region 236.

The processing region 236 generally includes at least one inlet 240 and outlet 238 that provide for entrance and egress of fluids to the plenum. The inlet 240 and outlet 238 are fluidly coupled to a respective inlet port 244 and outlet port 242 disposed on the clamp plate 210. Typically, the inlet 240 and outlet 238 are disposed in a spaced-apart relation on the processing region 236, and preferably at opposite corners of the square area defined by the processing region 236 to promote efficient flow through the processing region 236 and thereby minimizing the mixing or cross-talk between fluids during fluid change.

During processing, the inlet 240 is generally disposed under the outlet 238 to enhance entry and drainage of fluids from the processing region 236. Alternatively, flowcell 200 may be orientated so that the inlet 240 is disposed at the highest point of the processing region 236. Preferably, fluids are introduced and drained from the process region 236 through the inlet 240 while the outlet 238 is vented. Fluids additionally may be allowed to stand within the flowcell 200 to ensure ample mixing and reaction throughout the process region 236. Since the chemical processes within the flowcell 200 are generally a function of mixing which is affected by fluid velocities and distribution within the processing region 236, allowing fluids to stand within the flowcell 200 substantially eliminates non-uniformity during processing.

A back side 246 of the clamp plate 210 generally includes the inlet port 244 and outlet port 242 along with one or more optional locating features (not shown). Generally, the inlet port 244 and outlet port 242 interface with the fluid delivery system described below and may additionally contain luer, leak-tight or other fittings adapted to facilitate fluid transfer and/or retention (such as a check valve).

Optionally, the ports 242 and 244 may be disposed on the backplate 208 so that the fluid paths are disposed through one less component and part seam further minimizing mixing or cross-talk between fluids during fluid changes. In such a configuration, fittings disposed in the ports 242 and 244 are access through holes in the clamp plate 210, and as such, the clamp plate 210 does not have to be comprised of a material compatible with the process fluids.

In the embodiment shown in FIGS. 2A and 2B, the wafer 212 is depicted as having a square form, and accordingly, to minimize the processing region 236 of the gasket 206, face plate 202 and processing region 236 are also in square form. However, in embodiments not shown and having other wafer geometries may be readily devised by one skilled in the art following the disclosure herein.

FIG. 4 depict another embodiment of a flowcell 400. The flowcell 400 generally includes a face plate 402, a gasket 404 and a backplate 406. The face plate 402, gasket 404 and backplate 406 generally clamp a wafer 414 therebetween similar to the flowcell 100 described above.

The face plate 402 may be comprised of any relatively rigid material, such as aluminum, stainless steel, quartz, ceramic, rigid or reinforced polymer or similar suitable material. In the embodiment illustrated in FIG. 4, a reinforcing ring 408 is fastened to the face plate 402 by a plurality of screws 410 that thread into a threaded hole 412 disposed in the reinforcing ring 408.

The gasket 404 is generally fabricated form a material compatible with the materials, reagents and other fluids utilized in the flowcell 400. Examples of some materials that may be utilized include polytetrafluoroethylene, nitrile, silicone and the like. The gasket 404 may have various sectional profiles such as rectangular, round or other profile. Additionally, a portion of the gasket 404 may be disposed in a groove 412 disposed backplate 406 to assist in maintaining the position of the gasket 404 during clamping of the wafer 414. Alternatively, the gasket 404 may be located in other manners.

Generally, the gasket 404 maintains the wafer 414 in a spaced-apart relation relative the backplate 406 thereby defining a plenum therebetween. Typically, the depth of the plenum (i.e., the distance between the backplate 406 and wafer 414) is between about 0.6 mm to about 6 mm.

The area of the backplate 406 defined within the gasket 404 defines a processing region 416. As the processing region 416 is exposed to the fluids and materials processed in the flowcell 400, the backplate 406 should be comprised of a process compatible material, for example polytetrafluoroethylene, acrylonitrile butadiene styrene, stainless steel and other compatible materials.

The processing region 416 generally includes a fluid distribution groove 418 and a drain groove 420. The fluid distribution groove 418 is typically orientated across a first side 422 of the processing region 416 while the drain groove 420 is typically orientated across a second side 424 of the processing region 416 that is positioned opposite the first side 422. The position of the grooves 418, 420 on opposite sides of the processing region 416 enhances the uniformity of the fluid delivery across the entire processing region 416 during process.

In another mode of operation, the fluid distribution groove 418 is utilized as both an inlet and an outlet for fluids delivered to the processing region 416. The drain groove 420 is generally positioned above the fluid distribution groove 418 and is utilized as a vent. Optionally, the drain groove 420 may be configured as a circular passages similar to the other flowcells.

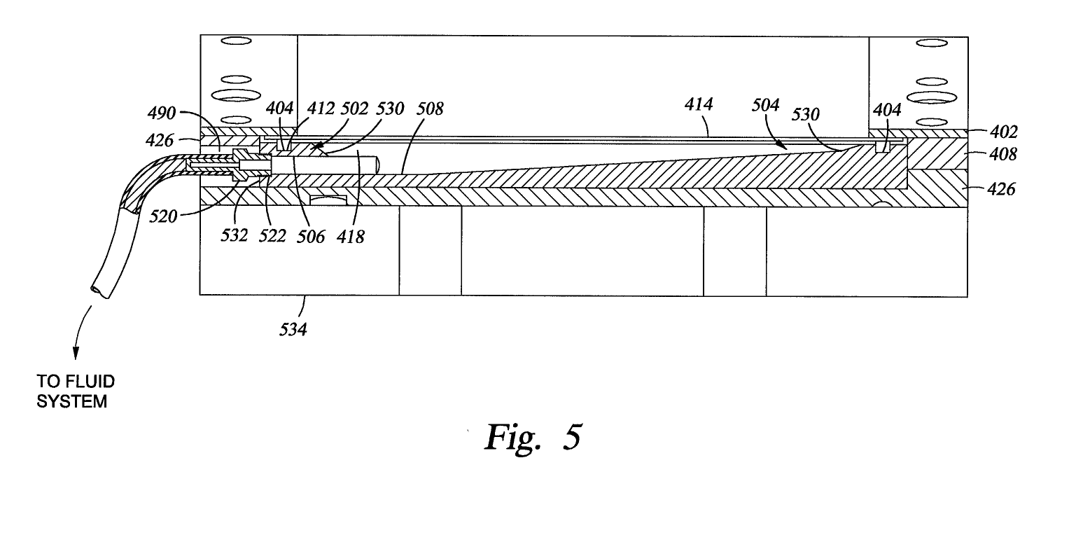

FIG. 5 depicts a sectional view of one embodiment of the fluid distribution groove 418 of the flowcell 400 of FIG. 4. Generally, the fluid distribution groove 418 is formed into the backplate 406 and has a first end 502 and a second end 504. The first end 502 typically has an aperture 506 that fluidly couples the fluid distribution groove 418 the fluidic system described below. The aperture 502 may be disposed at a bottom 508 of the fluid distribution groove 418 or through another portion of the backplate 406. Generally, the sectional area of the distribution groove 418 is greatest proximate the aperture 502 and diminishes at distances along the groove 412 further from the aperture 506. The varied sectional area of the first distribution groove 506 promotes uniform flow of fluid to the processing region 416 along the entire length of the groove 418. In the embodiment depicted in FIG. 5, a depth of the fluid distribution groove 418 at the first end 502 is greater than a depth of the fluid distribution groove 418 at the second end 504 so that fluid flowing through the fluid distribution groove 418 is uniformly distributed into the processing region 416 between the ends 502, 504. The ends 502, 504 may additionally include rounded corners 530 to enhance flow and minimize trapping of fluid. Variation of the sectional area of the groove 418 may be provided in other manners.

The aperture 506 generally couples the fluid distribution groove 418 to an inlet port 520 disposed in the backplate 406. The inlet port 520 may be disposed in an edge 532 of the backplate 406 as shown, or in a back surface 534 opposite the processing region 416. The inlet port 520 is generally configured to accept a leak-tight fitting 522 such as a flat bottom fitting, luer fitting, tube nipple and other leak-tight couplings. The fitting 522 is accessed through a hole 490 disposed at least partially in the stiffening plate 426 and/or reinforcing ring 408 (as shown in FIGS. 4 and 5). Optionally, the inlet port 520 may be disposed in the stiffening plate 426 as described with reference to the flowcell 200. The second fluid distribution groove 420 is similarly configured.

Returning to FIG. 4, the flowcell 400 is generally releasably fastened together with a plurality of fasteners, clips or adhesives. In the embodiment depicted in FIG. 4, a plurality of screws 450 are inserted respectively through holes 452, 454, 466 in the reinforcing ring 408, face plate 402 and backplate 406 and into threaded holes 458 disposed in the stiffening plate 426.

To maintain alignment between the reinforcing ring 408, face plate 406, backplate 408 and stiffening plate 426, one or more assembly alignment features 460 similar to those described above are utilized. In one embodiment, the assembly alignment features 460 include tabs 462 and pins 464. The tabs 462 generally extend from the perimeter of the backplate 406 and interface with mating slots 466 disposed in the stiffening plate 426. The pins 464 generally extend from the stiffening plate 426 and pass through holes 468 disposed in the backplate 406. Optionally, the pins 464 may interface with holes (not shown) in the face plate 402.

As described with above with reference to flowcells 100, 200 and 300, the flowcell 400 may include various locating features 470 that includes one or more pins, holes, slots, mating features or other elements or geometry that assists in aligning the flowcell 400 relative to another object or device such as a transfer plate 472. In the embodiment illustrated in FIG. 6, the flowcell 400 has locating features 470 that include at least one groove 602 disposed in at least a first side 604 of the flowcell 400. The flowcell 400 may additionally include locating features 470 on the same or other sides of the flowcell 400. For example, the flowcell 400 may include one or more blind holes, tabs, slots, threaded holes or other locating features 470 as described with reference to the flowcells 100, 200 and 300 described above. Having the locating features 470 disposed on the sides of the flowcell 400 enhances the handling characteristics of the flowcell 400 facilitating flexible interfaces with other devices or systems.

B. Flowcell Cassette

The flowcell cassette is generally used to retain a plurality of flowcells for processing in the fluidic system described below. The cassette additionally provides a convenient device for transferring and processing the cassette in other systems, for example, an incubation oven such as a modified GeneChip® Hybridization Oven 640, available from Affymetrix Inc., of Santa Clara, Calif. Utilization of the flowcell cassette in such process systems allows flexible processing. For example, as cassettes have the same exterior geometry may be used interchangeably in a process system, a first cassette having a flowcell of one size or shape may be processed immediately after a second cassette configured to accommodate a flowcell sized different than the first without interruption to reconfigure the process system to accommodate a different size flowcell.

The cassette generally allows multiple flowcells, each containing a whole wafer to be processed either sequentially or in a batch. As the multiple wafers are positioned in a processing unit such as the fluidic system described below in unison, substantial cycle time is saved relative to systems that sequentially process individual wafers or portions thereof (chips).

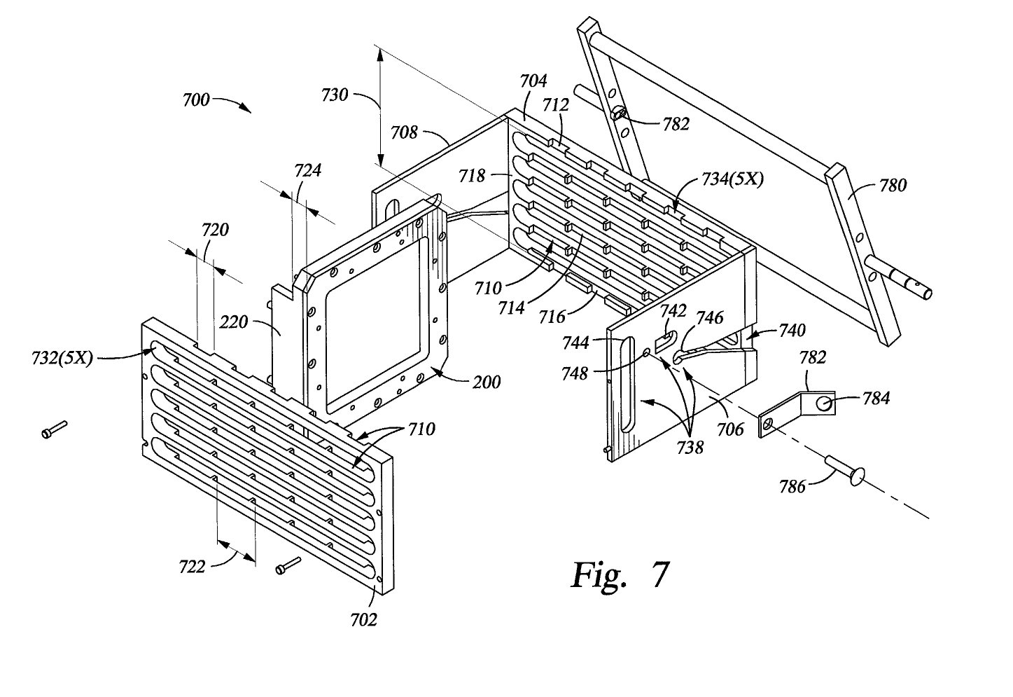

FIG. 7 depicts an exploded view of one embodiment of a flowcell cassette 700 configured to retain a plurality of flowcells. Although the embodiment of the cassette 700 illustrated in FIG. 7 is shown interfacing with the flowcell 200 of FIGS. 2A and 2B, one skilled in the art will readily identify that other embodiments of flowcell cassettes may be devised to interface with flowcells of this and other configurations, all of which are intended to be encompassed within the teachings disclosed and claimed herein.

Generally, the cassette 700 includes a front panel 702, a back panel 704, and side panels 706, 708. The side panels 706, 708 are generally coupled to the front and back panels 702, 704 to maintain the front and back panels 702, 704 in a spaced-apart relation that accommodates the flowcells therebetween. Typically, the front panel 702 is removable from the sides 706, 708 via a plurality of fasteners 736 to allow for the flowcells 200 to be quickly inserted and removed from the cassette 700 with minimal effort. The fasteners 732 may include, but are not limited to, screws, quarter-turn fasteners, latches, ball plungers and other quick-release or temporary fastening devices. The panels 702, 704, 706 and 708 may be fabricated from a rigid material preferably compatible with process and other fluids utilized in the fluidic system, such as aluminum, stainless steel, rigid or reinforced polymer or similar suitable material.

Typically the front and back panels 702, 704 include a plurality of interface features 710 which are utilized to secure flowcells 200 therebetween in a predetermined position. The interface features 710 generally mate with the locating features of the flowcells 200 described with reference to FIG. 4 above, and, as such, may vary by choice of design. Cassettes configured for use with other flowcells, including those described in FIGS. 1-3 above, may incorporate the same, additional or different locating features as desired.

In the embodiment depicted in FIG. 7, the interface features 710 include a plurality of feature sets 734 formed in the front and back panels 702, 704. Each feature set 734 generally secures a single flowcell 200 therebetween. Each feature set 734 generally comprises upper, intermediate and lower slots 712, 714, 716, respectively, formed in an interior wall 718 of the front and back panels 702, 704. The number of feature sets 734 provided are generally dependent on the size of the fluidic system and the number of flowcells utilized, and in the illustrated embodiment, comprises five feature sets 734 to accommodate five flowcells 200 within the cassette 700.

Generally, the upper and lower slots 712, 716 of each feature set 734 have a width 720 less than the width 722 of the intermediate slot 714. The width 720 is selected to accommodate a width 724 of the flowcell 200. The intermediate slot 714 generally is configured to mate with the tab 220 of the flowcell 200. Accordingly, the width 714 and a height 730 of the intermediate slot 714 allows the tab 220 to be securely nested therebetween. The front panel 702 typically includes interface features 710 that are mirror images of the slots 712, 714 and 716 of each feature set 734.

Generally, the four panels 702, 704, 706 and 708 comprising the cassette 700 form an open frame. Although the cassette 700 may optionally include a top and/or bottom (not shown) partially enclosing the interior of the cassette 700, the open configuration of the cassette 700 provides good access to the flowcells 200 by the fluidic system described below and additionally allow good circulation around the flowcells 200 thereby enhancing temperature control and promoting incubation. To further enhance circulation around the flowcells 200, a plurality of vents 732 are disposed through the front and back panels 702, 704. Additional vents (not shown) may be disposed through the side walls 706, 708. In one embodiment, the number, size and position of the vents 732 are selected to substantially align the cassette's center of gravity and the cassette's chosen axis of rotation.

The side panels 706, 708 typically contain one or more locating features 738 that ensure the location of the cassette 700 within the fluidic system or other system or device interfacing with the cassette 700. As with the other locating features described herein, the locating features 738 are subject to design choice and thus may vary in type, shape and number.

In the embodiment illustrated in FIG. 7, the locating features 738 disposed on each of the side panels 706, 708 include a tapered first slot 740, a second slot 742 and a third slot 744. Generally, the first slot 740 extends from a circular hole 746 disposed near the projected center of gravity of the cassette 700 to an edge of the side panels 706, 708 adjoining the back panel 704. In embodiments where the side panels 706, 708 are disposed between the front and back panels 702, 706, the first slot 740 extends through the back panel 702 to allow a mating feature, for example a tab 782 disposed on an cassette adapter 780, to be slid and guided from the open end of the tapered first slot 740 to the circular hole 746. Any one of the slots may additionally be configured as a handle (for example, the third slot 744) whether or not it is used as a locating feature 738. The locating features 738 may additionally include other holes, projections, tabs and the like such as a threaded hole 748. In one embodiment, a flat spring 782 having a formed metal button 784 is fastened by a screw 786 or other device to the hole 748 disposed in the side plate 706 of the cassette 700.

C. Cassette Adapter

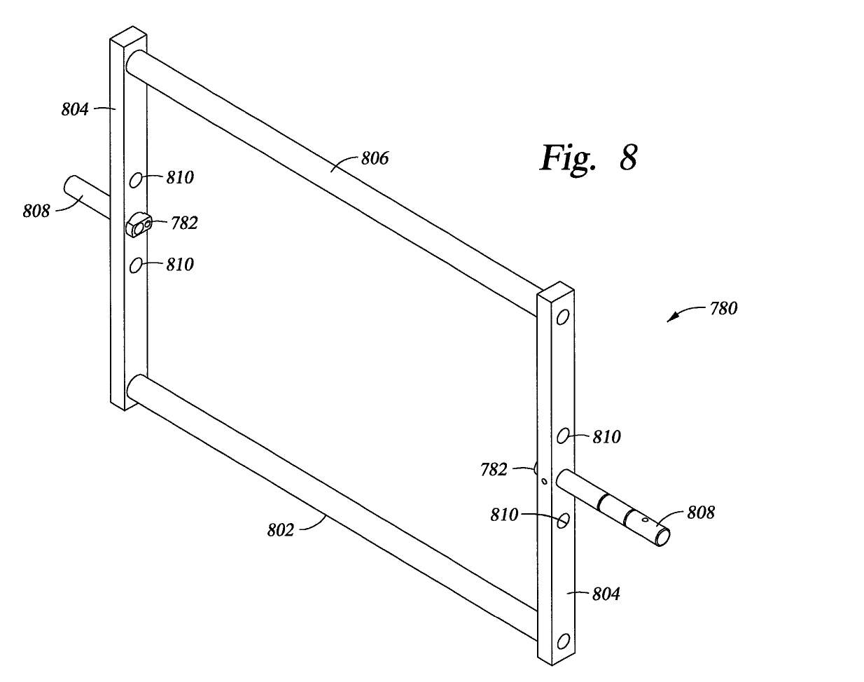

FIG. 8 depicts one embodiment of a cassette adapter 780 that may be utilized with the cassette 780. The particular adapter 780 illustrated in FIG. 8 is configured to allow the cassette 780 to be controllably rotated about an axis disposed through the side panels 706, 708. Generally, the cassette adapter 780 is fabricated from stainless steel, aluminum or other rigid material and includes a pair of side bars 804 interconnected at their ends by rods 806. Proximate the center of each side bar 804, a shaft 808 projects outwardly from the adapter 780. The mounting tab 782, generally utilized to interface with the cassette 780 as described above, projects inwardly from each side bar 804 opposite the shaft 808. A through hole 810 is generally disposed through the side bars 804 on both sides of the shaft 808.

Referring to both FIGS. 7 and 8, the cassette adapter 780 is generally mounted to the cassette 700 by sliding the mounting tab 782 through the first slot 740 of the cassette 700 until the tab 782 resides in the hole 746. The adapter 780 is then rotated until the metal button 822 springs into one of the holes 810, thus aligning the side plate 706 of the cassette 700 with the adapter 780. A fastener (not shown) is passed through the hole 810 and threaded into the hole 748 to secure the cassette adapter 780 to the cassette 700. The shafts 808, now positioned outward from the center of gravity of the cassette 700, provide a pivot point from which the cassette 700 can be controllably rotated. For example, the cassette adapter 780 may be removably or permanently mounted the shafts 808 within an oven, fluidic station or other system, to receive and hold the cassette 700 during processing. The shafts 808 allow the cassette 700 with flowcells 200 and wafers 212 disposed therein to be rotated and/or agitated to enhance processes such as fluid process and incubation of the material disposed on the wafer. Optionally, the shafts 808 may be coupled to the cassette 700 directly.

D. Fluidic System

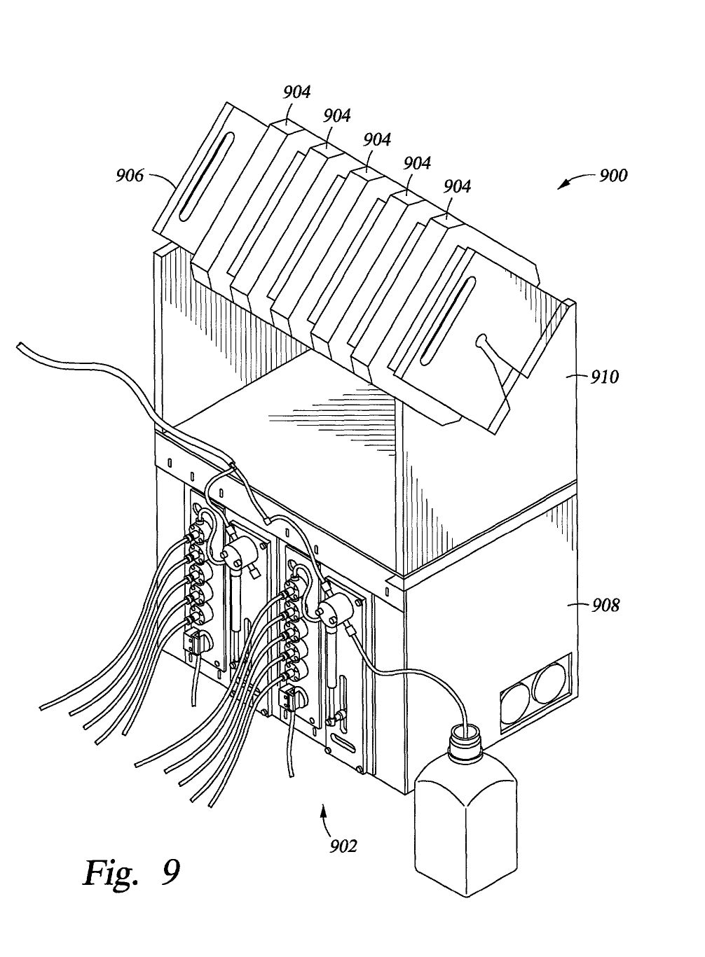

FIG. 9 depicts one embodiment of a fluidics system 900. Generally, the fluidics system 900 typically includes at least one fluid delivery module 902 for delivering a sample-containing fluid, a wash fluid, a buffer, or the like, to a plurality of flowcells 904 disposed in a flowcell cassette 906 (showing with the front panel removed allowing the flowcells to be viewed). In the embodiment depicted in FIG. 9, the flowcell cassette 906 is disposed in a cradle 910 that is disposed adjacent to an enclosure 908. The proximity of the cassette 906 to the fluid delivery module 902 minimizes the lengths of tubing coupling the flowcells 904 to the module 902, conserves fluids and reduces cycle time. The cradle 910, positioned in front of the enclosure 908 in FIG. 9, generally secures the cassette 906 during processing while maintaining the proper orientation of the flowcell 904. Alternatively, the cradle 910 and cassette 906 may be disposed in other positions relative to the fluid delivery module 902 or be remotely located.

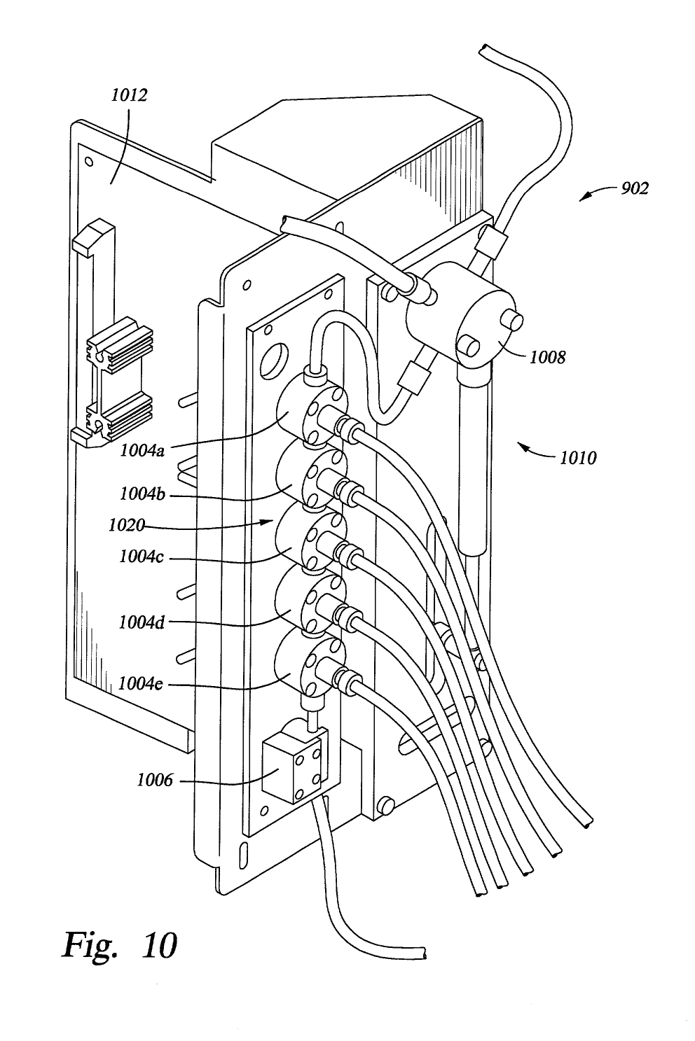

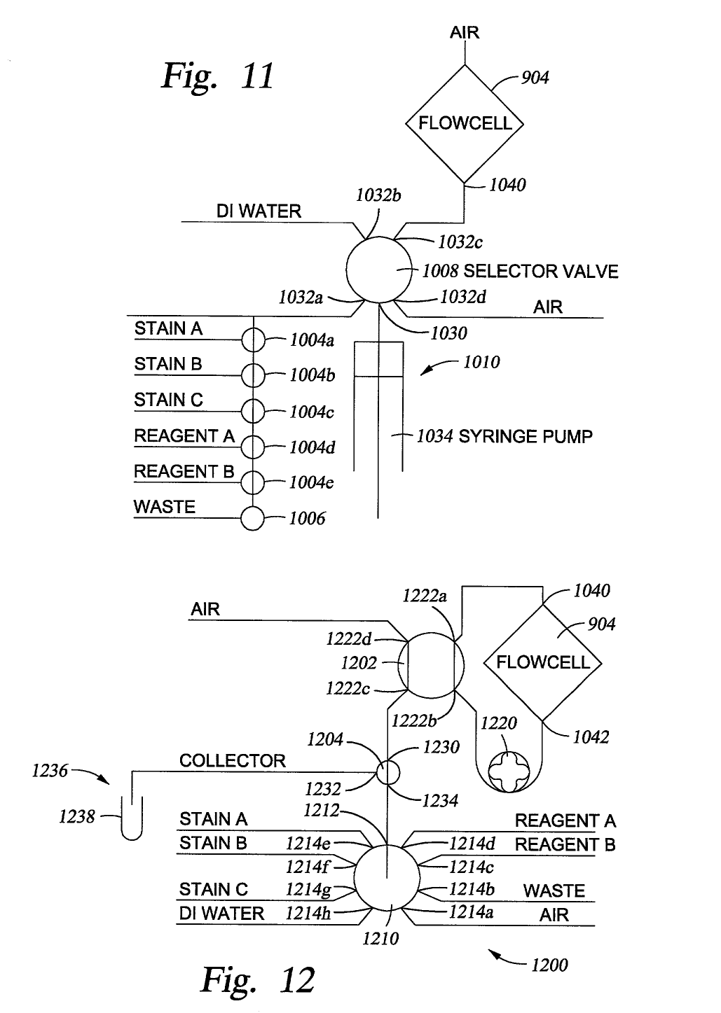

As depicted in FIG. 10 and the accompanying flow schematic of FIG. 11, the fluid delivery module 902 generally includes a valve train 1020 comprising a plurality of process valve assemblies 1004(a-e), a waste valve assembly 1006, a selector valve 1008, and an injection system 1010 for introducing the fluid into the flowcell 904 (shown in FIG. 9). Generally, the selector valve 1008 and valve train 1020 are utilized to selectively couple a particular fluid source to the injection system 1010. The injection system 1010 draws and/or meters fluid from the source coupled thereto, and then delivers the fluid to one or more of the flowcells 904.

The valve train 1020 is generally fluidly coupled between the waste valve assembly 1006 and the selector valve 1008. Each process valve assembly 1004 has an outlet port commonly coupled within the valve train 1020 and an inlet port coupled to a fluid source. For example, process valve assembly 1004a is coupled to STAIN A, process valve assembly 1004b is coupled to STAIN B, process valve assembly 1004c is coupled to STAIN C, process valve assembly 1004d is coupled to REAGENT A and process valve assembly 1004e is coupled to REAGENT B. The valve assemblies 1004 are typically logic operated, for example by electrical or pneumatic signals, and are generally coupled to a logic control board 1012 that is coupled to the system controller or user interface (not shown). Thus, if, for example, STAIN C is required within the flowcell 904, process valve assembly 1004c is actuated to allow the injection system 1010 to draw STAIN C through the valve train 1020 and selector valve 1008. Once the desired amount of STAIN C is disposed in the injection system 1010, the selector valve 1008 couples the injection system 1010 to the flowcell 904 and STAIN C is delivered to the flowcell 904. The waste valve assembly 1006 may be opened to drain fluids disposed between the selector valve 1008 and valve train 1020 after the injection of STAIN C and before the transfer of another fluid to the flowcell 904.

The waste valve assembly 1006 is generally a shut-off valve. Examples of valves that may be utilized as a waste valve assembly 1006 include, but are not limited to, pinch valves, poppet valves, diaphragm valves, gate valves, ball valves, rotary valves and the like.

The selector valve 1008 generally is a multi-port rotary valve having a common port 1030 that can be selectively coupled to secondary ports 1032a-d. Selector valves having more secondary ports may be utilized, for example, to remove expensive reagents from the valve train 1020 to minimize fluid consumption. Generally, the common port 1030 is coupled to the injection system 1010. In the embodiment depicted in FIG. 11, the secondary port 1032a is coupled to the valve train 1020, the secondary port 1032b is coupled to deionized water, the secondary port 1032c is coupled to room air or gas source and the secondary port 1032d is coupled to one or more of the inlet ports 1040 of the flowcells 904 disposed in the cassette 906. The gas source generally supplies a gas, for example, an inert gas such as nitrogen. Optionally, fluids may be coupled directly to the selector valve 1008 to minimize the volume of fluids that wasted when transferred through the valve train 1020.

The injection system 1010 is generally a pump or other flow device. Optionally, pressurized fluid systems (i.e., pressurized stains, reagents, etc.) may not require an injection system 1010 as the fluid flows may be driven by the system pressure. The injection system 1010 typically comprises a positive displacement pump, solenoid pump, gear pump, peristaltic pump or the like. Preferably, the pump is a motorized syringe pump 1034. Generally, the capacity of the syringe pump 1034 is selected based on the volume of the flowcells 904 to be serviced by the fluid delivery module 902. In the embodiment depicted in FIG. 11, the system 900 includes two delivery modules 902 that are each coupled to two flowcells 904. Preferably, each delivery module 902 is coupled to a single flowcell 904 to ensure uniform fluid delivery between flowcells 904. Thus, having whole wafers processed on the system 900 greatly increases throughput relative to chip processing systems.

FIG. 12 depicts a schematic of another embodiment of a fluid delivery module 1200. Generally, the fluid delivery module 1200 includes a selector valve 1210, a collector valve 1204, a diverter valve 1202 and a injection system such as a circulation pump 1220. The selector valve 1210 is generally a rotary valve having a common port 1212 and a plurality of secondary ports 1214a-h. The common port 1212 is coupled to the collector 1204 which serves as an accumulator between the diverter valve 1202 and the selector valve 1210. The secondary ports 1214a-h are respectively coupled to room air, waste, REAGENT B, REAGENT A, STAIN A, STAIN B, STAIN C, and DI WATER. The logic control board 1012 or other control device, local or remote, generally actuates the selector valve 1210 such that any one of the ports 1214a-h may be coupled to the common port 1212. Having all the fluids coupled to the selector valve 1210 provides a fully swept, low volume flow path between the fluid sources and the flowcell 904 while minimizing the number of valves utilized.

The diverter valve 1202 generally has four ports 1222a-d. Generally, ports 1222a and 1222b are respectfully coupled to an inlet port 1040 and an outlet port 1042. When the diverter valve 1202 is in a first state the ports 1222a-b are coupled allowing the inlet port 1040 and outlet port 1042 of the flowcell 904. Generally, the circulation pump 1220, such as a gear or peristaltic pump, is coupled between one of the inlet or outlet ports 1040, 1042 and the diverter valve 1202 so that fluid within the flowcell may be re-circulated therethrough a number of times in a loop. Circulating the fluid in this manner enhances the process results while conserving process fluids and minimizing waste.

Upon actuation of the diverter valve 1202, the inlet port 1040 is coupled through ports 1222a and 1222c to the collector 1204 so that the selected fluid may be injected into the flowcell 904 by the circulation pump 1220. In this state, room air may be coupled to the flowcell 904 through ports 1222d and 1222b to allow fluids to be drained out of the flowcell 904 back through the ports 1222a and 1222c to the waste line coupled to the secondary port 1214b.

The collector valve 1204 is generally a diverter valve having a common port 1230 coupled to the diverter valve 1202. The collector valve 1204 additionally includes a first port 1232 coupled to a collection system 1236 and a second port 1234 coupled to the common port 1212 of the selector valve 1210. The collector valve 1204, when in a first state, allows fluids to pass directly between the selector valve 1210 and the diverter valve 1202. The collector valve 1204, when actuated to a second state, diverts fluid from the diverter valve 1202 to the collection system 1236.

Collection system 1236 generally allows sample and/or other fluids passing from the flowcell 904 to be collected for further use. In one embodiment, the collection system 1236 includes a container 1238 such as a beaker, test tube, flask or other fluid holding apparatus which may be mounted to or proximate the delivery module 1200.

Although the delivery module 1200 is depicted as coupled to a single flowcell, the module may be configured to deliver fluid to additional flowcells, for example, through additional ports in the selector valve 1210 or tee's in one or more of the fluid lines.

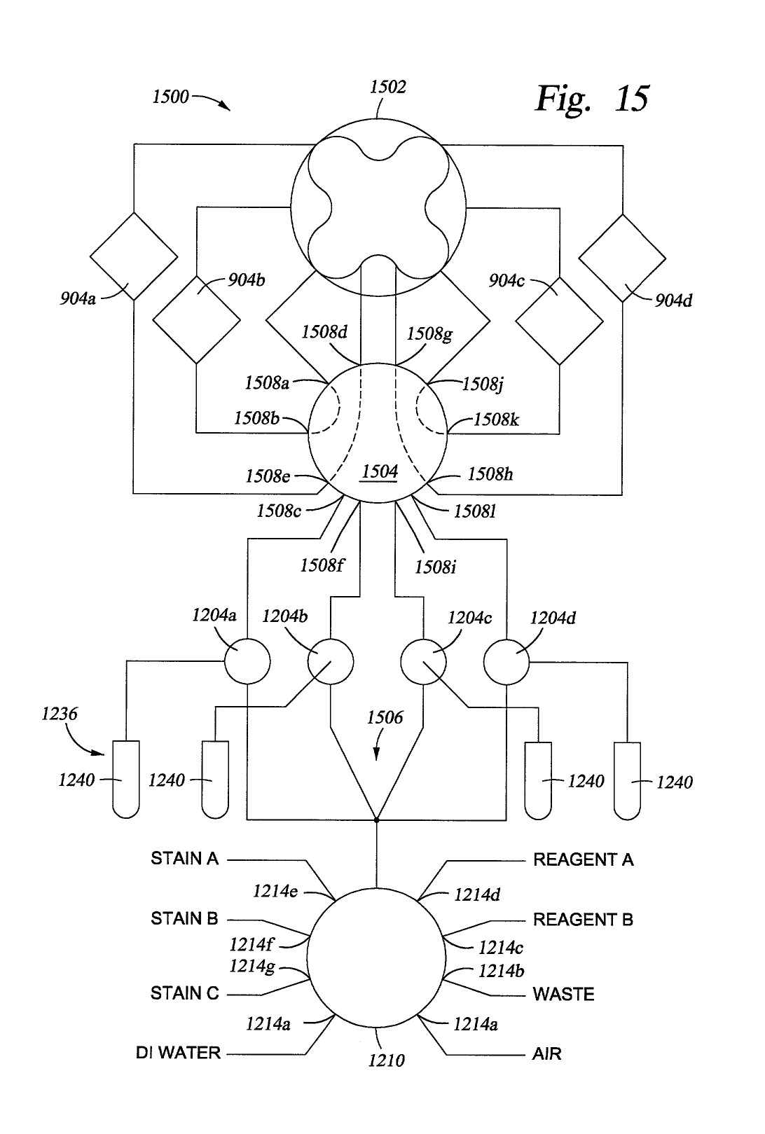

FIG. 15 depicts a schematic of another embodiment of a fluid delivery module 1500. The module 1500 is generally similar to the module 1200 except where a pump 1502 of the module 1500 is configured to deliver fluids through a plurality of flowcells 904a-d. Generally, the common port 1212 of the delivery module 1200 is coupled to a tee or manifold 1506. The tee 1506 couples the common port 1212 to a plurality of collector valves 1204a-b. Each collector valve 1204a-b is coupled to a respective, individual collection system 1236.

A diverter valve 1504 has ports 1508c, 1508f, 1508i and 1508l that selectively couple a respective flowcell 904a-d with a respective collector valve 1204a-d. The diverter valve 1504 may be configured such that only one flowcell is coupled to a collector valve or that a plurality of flowcells (i.e, two or more flowcells) may be coupled to the collector valve. In the embodiment of FIG. 15, the diverter valve 1504 has a first state that couples the flowcells 904a-d with the collector valves 1204a-d. In the first state, the pump 1502, such as a multi-tube peristaltic pump, draws fluids from the selector valve 1210 through the respective collector valves 1204a-d and into a respective flowcell 904a-d. In a second state, the diverter valve 1504 allows the pump 1502 to circulate the fluids within the flowcells 904a-d by creating a loop through the diverter valve 1504 and flowcells 904a-d. For example, the fluids within flowcell 904a are drawn by the pump 1502 through a port 1508a of the diverter valve 1504 that is coupled to the flowcell 904a. The fluids pass through the diverter valve 1504 from the port 1508a to a port 1508b which is coupled to the flowcell 904a. The other flowcells 904b-d respectively make isolated flow circuits through the diverter 1504 and pump 1502 utilizing ports 1508d-e, g-h and j-k. The configuration of the delivery module 1500 allows multiply flowcells to be processed simultaneously with minimal hardware while maintaining process isolation between flowcells and selective sample and fluid recovery

E. Cradle

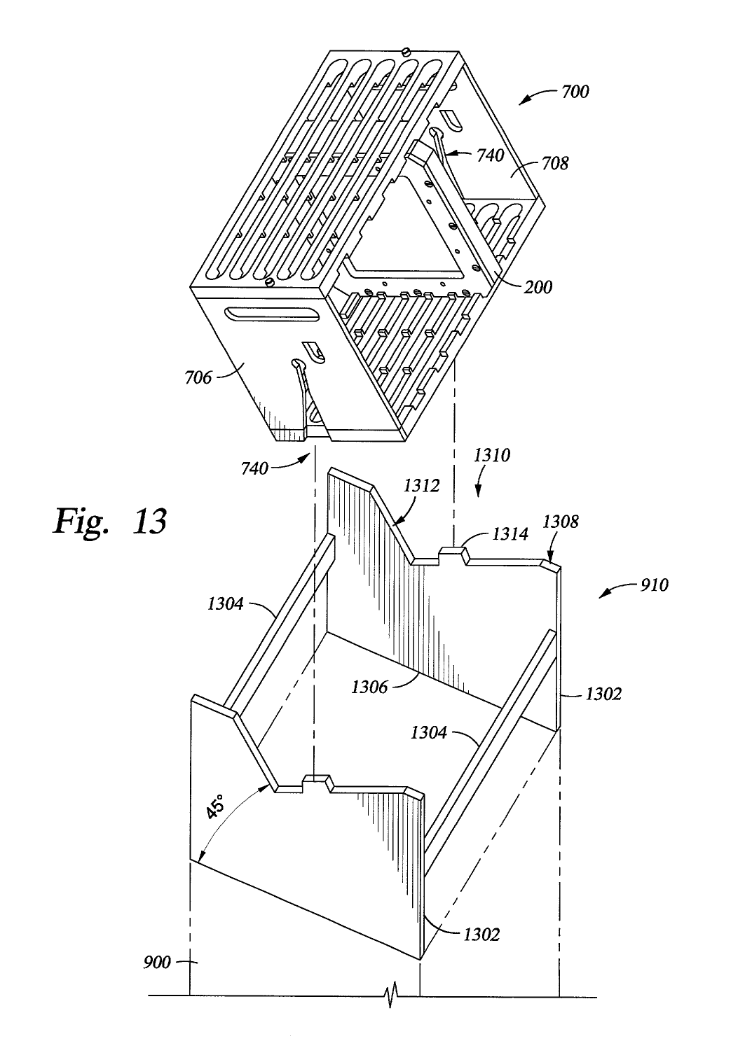

FIG. 13 depicts one embodiment of a cradle 910. The cradle 910 generally comprises two support members 1302 having one or more longitudinal supports 1304 coupled therebetween. Generally, the support members 1302 have a bottom side 1306 and a top side 1308. The bottom side 1306 is generally adapted to support the cradle 910 on a surface, and, as in the embodiment depicted in FIG. 9, the support members 1302 are adapted to couple the cradle 910 to the fluidic system 900.

The cradle 910 generally includes one or more interfacing features 1310 that are adapted to maintain the cassette 700 and flowcells 200 (only one is shown) disposed therein in a predetermined position (i.e., maintain an orientation that promotes advantageous fluid flow within the flowcells). In the embodiment depicted in FIG. 13, the interfacing features include a V-shaped notch 1312 disposed in the top side 1308 of the support members 1302. The V-shaped notch 1312 is configured to maintain the cassette 700 in a 45 orientation relative to the bottom side 1306 of the cradle 910. The interface features 1310 may also include additional elements, for example, a tab 1314 projecting from one side of the V-shaped notch 1312 which interfaces with the first slot 740 disposed in the side panels 706, 708 at the cassette 700. As the interface features 1310 maintain the orientation of the cassette 700 relative to the cradle 910, one skilled in the art will be able to devise other interfacing features that provide the desired orientation, including those not disposed on the supporting members 1302, for example, an “L” or U-shaped” tray disposed on the longitudinal supports 1304.

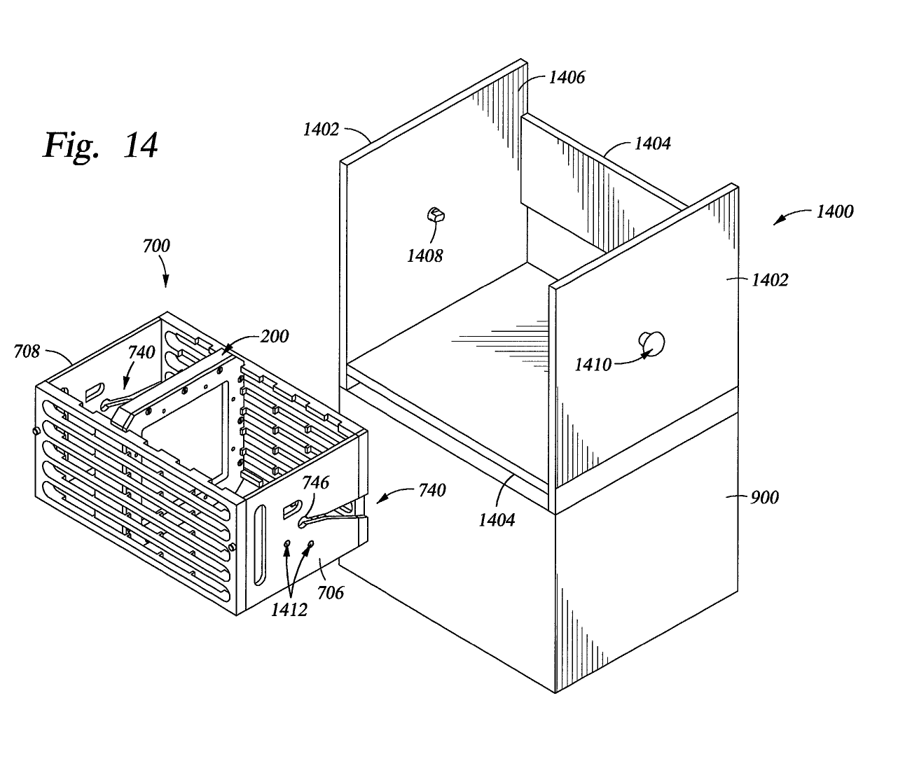

FIG. 14 depicts another embodiment of a cradle 1400 disposed on the system 900. The cradle 1400 generally includes support members 1402 having one or more longitudinal supports 1404 coupled therebetween. An inner wall 1406 (only one shown in FIG. 14) of each support member 1402 includes a circular post 1408 projecting therefrom. The post 1408 is configured to slide within the first slots 740 disposed in the side panels 706, 708 of the cassette 700. Upon complete insertion of the cassette 700 between the support members, the post 1408 resides in the circular hole 746 disposed at the end of the first slot 740 and cooperate therewith, allowing the cassette 700 to rotate between the support members 1402.

The support members 1402 additionally contain one or more catch assemblies 1410 adapted to selectively fix the orientation of the cassette 700 within the cradle 1400. Generally, the catch assembly 1410 interfaces with one or more holes 1412 disposed in the side panels 706, 708 of cassette 700. The catch assembly 1410 is positioned to interface with two of the holes 1412 disposed in the cassette 700 that are positioned equidistant from the circular hole 746, thus allowing the cassette (and flowcell therein) to be orientated relative the cradle 1400 in a predetermined position. The flexibility of the cradle 700 to allow multiple angular orientations of the flowcell cassette 700 allows the same cassette to be used with flowcells requiring different angular orientations during processing. For example, the cassette 700 and cradle 1400 may be used with a flowcell such as described with reference to FIGS. 1A and 1B requiring a 45 angle during a first process batch, then the cassette 700 (or replacement cassette) may be disposed in the cradle 700 having a flowcell such as described with reference to FIGS. 4 and 5 which requires a vertical orientation during processing. This flexibility allows subsequent processing of flowcells having different configurations with negligible set-up time between batches.

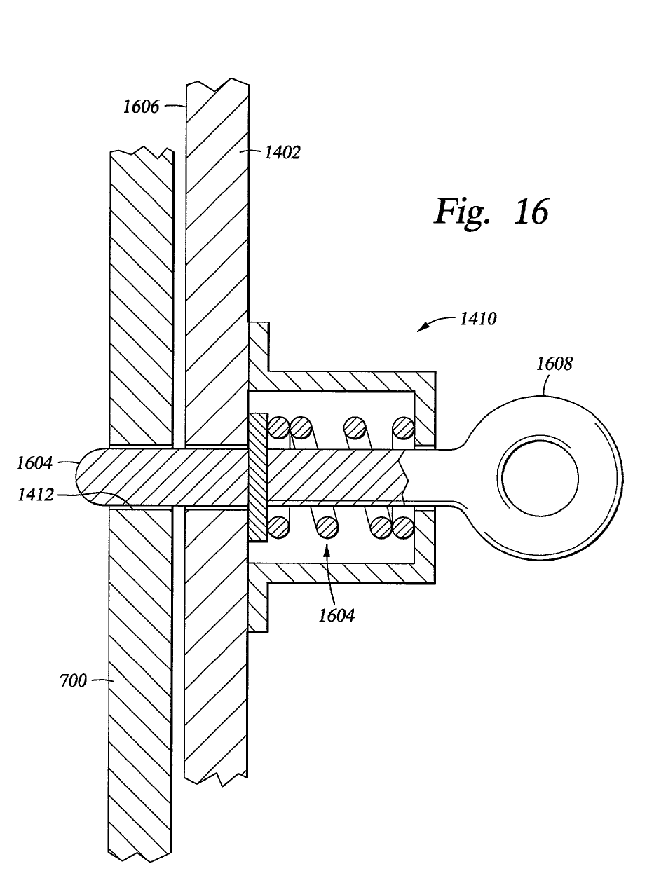

FIG. 16 depicts one embodiment of the catch assembly 1410. The catch assembly 1410 generally includes a spring-loaded piston 1502 that biases a pin 1504 to project outward from the inner surface 1506 of the support member 1402. The catch assembly 1410 includes a knob 1508 which facilitates retracting the pin 1504 against the spring bias to hold the end of the pin 1504 substantially flush with the inner surface 1506 of the support member 1402. As the cassette 700 rotates to a position where a loading feature (i.e., a hole of the cassette) aligns with the catch assembly 1410, the spring biases the pin 1504 outward from the support member 1402 and into the hole 1412, thereby securing the cassette 700 in a predetermined angular orientation for processing. One skilled in the art will readily recognize that other types of catch mechanisms may be adapted to retain the cradle in any desired orientation relative to the cradle. For example, the cradle 1400 may be adapted to accommodate the cassette adapter 780 to provide selectable orientation of the cassette 700 and flowcells retained therein.

Although various embodiments which incorporate the teachings of the present invention have been shown and described in detail herein, those skilled in the art can readily devise many other varied embodiments that still incorporate these teachings.

What is claimed is:

1. A flowcell for processing whole wafers, comprising:
a body;
a wafer;
a gasket disposed between the body and the wafer, the body, the wafer and the gasket defining a processing region therebetween;
a face plate urging the wafer towards the body;
an inlet disposed in the body and fluidly coupled to the processing region; and
an outlet disposed in body and fluidly coupled to a portion of the processing region opposite the inlet port.

2. The flowcell of claim 1, wherein the body further comprises:
a distribution groove formed in the body, the distribution groove exposed to the processing region and fluidly coupled to the inlet.

3. The flowcell of claim 2, wherein the distribution groove has a sectional area that varies along a length of the groove.

4. The flowcell of claim 3, wherein the sectional area of the distribution groove is greatest proximate the inlet.

5. The flowcell of claim 2, wherein the body further comprises:
an outlet groove formed in the body and fluidly coupled to the outlet, the outlet groove exposed to a portion of the processing region opposite the distribution groove.

6. The flowcell of claim 1, wherein the inlet and the outlet are disposed in opposite portions of the processing area.

7. The flowcell of claim 1, wherein the inlet and the outlet are disposed in opposite corners of the processing area.

8. The flowcell of claim 1, wherein the body further comprises:
a side opposite the processing region;
one or more edges bounding the side; and
an inlet port disposed in the side or one of the edges, the inlet port coupled to processing region through the inlet.

9. The flowcell of claim 1, wherein the body further comprises:
a groove circumscribing the processing region, the gasket at least partially disposed in the groove.

10. The flowcell of claim 1, wherein the body further comprises:
a groove circumscribing the processing region, the gasket projecting at least partially from the groove to define a portion of the processing region.

11. The flowcell of claim 1, wherein the body or face plate further comprises:
a boss extending between the wafer and body.

12. The flowcell of claim 1, wherein the body further comprises:
a recess formed in a portion of the body inwards of the gasket and bounding a portion of the processing region.

13. The flowcell of claim 1, wherein the body further comprises or is coated with aluminum, stainless steel, quartz, a ceramic, a polymer, acrylonitrile butadiene styrene, a reinforced polymer or polytetrafluoroethylene.

14. The flowcell of claim 1, wherein the gasket further comprises elastomers, perflouinated elastomers, polytetrafluoroethylene, nitrile, or silicone.

15. The flowcell of claim 1, wherein the wafer is at least 1 square inch.

16. The flowcell of claim 1 further comprising:
a reinforcing ring coupled to the faceplate.

17. The flowcell of claim 1 further comprising:
a backplate coupled to the faceplate and sandwiching the body therebetween.

18. The flowcell of claim 1, wherein the one or more of the backplate, body and faceplate further comprises:
one or more locating features for orientating the flowcell relative an external object.

19. The flowcell of claim 18, wherein the one or more locating features include one or more slots, projections, tabs and/or holes.

20. The flowcell of claim 19, wherein the one or more locating features are disposed on an edge of the flowcell.

21. A flowcell for processing whole wafers, comprising:
a body;
a wafer;
a gasket disposed between the body and the wafer, the body, the wafer and the gasket defining a processing region therebetween;
a recess formed in a portion of the body inwards of the gasket and bounding a portion of the processing region
an inlet disposed in the body and fluidly coupled to the processing region; and
an outlet disposed in body and fluidly coupled to a portion of the processing region opposite the inlet port.

22. The flowcell of claim 21, wherein the body further comprises:
a distribution groove formed in the body, the distribution groove exposed to the processing region and fluidly coupled to the inlet.

23. The flowcell of claim 22, wherein the distribution groove has a sectional area that is greatest proximate the inlet.

24. The flowcell of claim 22, wherein the body further comprises:
an outlet groove formed in the body and fluidly coupled to the outlet, the outlet groove exposed to a portion of the processing region opposite the distribution groove.

25. The flowcell of claim 21, wherein the inlet and the outlet are disposed in opposite portions of the processing area.

26. The flowcell of claim 21, wherein the body further comprises:
a groove circumscribing the processing region, the gasket at least partially disposed in the groove.

27. The flowcell of claim 21, wherein the body or face plate further comprises:
a boss extending between the wafer and body.

28. The flowcell of claim 21, wherein the wafer is at least 1 square inch.

29. The flowcell of claim 21 further comprising:
a reinforcing ring coupled to the faceplate; and
a backplate coupled to the faceplate and sandwiching the body therebetween.

30. The flowcell of claim 21, wherein the one or more of the backplate, body and faceplate further comprises:
one or more locating features disposed on an edge of the flowcell for orientating the flowcell relative an external object.

31. A flowcell for processing whole wafers, comprising:
a body;
a wafer;
a gasket disposed between the body and the wafer, the body, the wafer and the gasket defining a processing region therebetween;
a recess formed in a portion of the body inwards of the gasket and bounding a portion of the processing region
an inlet disposed in the body and fluidly coupled to the processing region;
an outlet disposed in body and fluidly coupled to a portion of the processing region opposite the inlet port; and
a distribution groove formed in the body, the distribution groove exposed to the processing region and fluidly coupled to the inlet.

32. The flowcell of claim 31 further comprising:
an outlet groove formed in the body and fluidly coupled to the outlet, the outlet groove exposed to a portion of the processing region opposite the distribution groove.

33. The flowcell of claim 31, wherein the distribution groove has a sectional area that is greatest proximate the inlet.

34. The flowcell of claim 31, wherein the body further comprises:
a groove circumscribing the processing region, the gasket at least partially disposed in the groove.

35. The flowcell of claim 31, wherein the body or face plate further comprises:
a boss extending between the wafer and body.

36. The flowcell of claim 31, wherein the wafer is at least 1 square inch.

37. The flowcell of claim 31 further comprising:
a reinforcing ring coupled to the faceplate; and
a backplate coupled to the faceplate and sandwiching the body therebetween.

38. The flowcell of claim 31, wherein the body further comprises or is coated with aluminum, stainless steel, quartz, a ceramic, a polymer, acrylonitrile butadiene styrene, a reinforced polymer or polytetrafluoroethylene.

39. The flowcell of claim 31, wherein the one or more of the backplate, body and faceplate further comprises:
one or more locating features disposed on an edge of the flowcell for orientating the flowcell relative an external object.

40. Apparatus for processing whole wafers comprising:
one or more flowcells having a wafer and body sandwiching a gasket; and
a cassette comprising a front panel disposed in a spaced-apart relation to a back panel, the front and back panels having a plurality of interface feature sets, each set partially disposed respectively on the front and back panels, each feature set adapted to retain one flowcell.

41. The apparatus of claim 40, wherein the cassette further comprises:
a first side coupled between the first panel and the second panel; and
a second side coupled between the first panel and the second panel opposite the first side; each side having a one or more locating features disposed thereon.

42. The apparatus of claim 41, wherein the locating features further comprises one or more slots, projections, tabs and/or holes.

43. The apparatus of claim 40, wherein the cassette further comprises:
a hole disposed in each side proximate a center of gravity of the cassette; and
a tapered slot extending from the hole to an edge of each panel adjacent the back panel.

44. The apparatus of claim 41, wherein the front panel is removably secured to the side panels by fasteners.

45. The apparatus of claim 41, wherein the front panel is removably secured to the side panels by latches, screws, quarter-turn fasteners, latches, ball plungers or other quick-release devices.

46. The apparatus of claim 40, wherein the cassette further comprises:
a first side coupled between the first panel and the second panel; and
a second side coupled between the first panel and the second panel opposite the first side, wherein the flowcell is orientated at about 45 degrees relative to the first side.

47. The apparatus of claim 40 further comprising:
shafts extending from the cassette defining an axis about which the front and back panels rotate.

48. The apparatus of claim 47, wherein the shafts extend from an adapter coupled to the cassette.

49. The apparatus of claim 48, wherein the cassette further comprises:
a spring having a button coupled to the cassette, the button engaging a hole disposed on the adapter.

50. The apparatus of claim 40, wherein the flowcell further comprises:
one or more locating features disposed on at least one edge of the flowcell, the locating features mating with the interface features.

51. The apparatus of claim 40, wherein the flowcell further comprises:
a recess disposed in the body inward of the gasket.

52. The apparatus of claim 40, wherein the flowcell further comprises:
at least one groove disposed in the body inward of the gasket; and
an inlet disposed in the body and fluidly coupled to one of the grooves.

53. Apparatus for processing a whole wafer comprising:
one or more flowcells having a wafer and body sandwiching a gasket;
a cassette comprising a front panel disposed in a spaced-apart relation to a back panel, the front and back panels having a plurality of interface feature sets, each set partially disposed respectively on the front and back panels, each feature set adapted to retain one flowcell; and
a fluidic station coupled at least one flowcell.

54. The apparatus of claim 53, wherein the fluidic station comprises:
a selector valve coupled to the flowcell;
at least one valve adapted to selectively open a fluid path to the selector valve; and
a pump for delivering fluid through the selector valve.

55. The apparatus of claim 54, wherein the selector valve is a rotary valve.

56. The apparatus of claim 54, wherein the selector valve further comprises:
a first port coupled to the flowcell; and
a second port coupled to atmosphere or a gas source.

57. The apparatus of claim 56, wherein the fluidic system further comprises:
an injection system coupled between the selector valve and the flowcell or coupled to a third port of the selector valve.

58. The apparatus of claim 56, wherein the at least one valve adapted to selectively open the fluid path to the selector valve further comprises:
a plurality of valves each having a port fluidly coupled together.

59. The apparatus of claim 58, wherein the at least one valve adapted to selectively open the fluid path to the selector valve further comprises:
a rotary valve having at least one port coupled to a stain supply, at least a second port coupled to a reagent supply, a third port coupled to air or a gas supply, and a fourth port coupled to deionized water.

60. The apparatus of claim 54, wherein the flowcell further comprises an inlet fluidly coupled to one port of the selector valve and an outlet fluidly coupled to another port of the selector valve.

61. The apparatus of claim 60, wherein the selector valve has a first state that provides a re-circulating flow path through the pump and the flowcell.

62. The apparatus of claim 54, where the fluidic station comprises:
a collector valve having a common port coupled to the selector valve, a first port coupled to a recovery line, and a second port coupled to the at least one valve adapted to selectively open the fluid path to the selector valve.

63. Apparatus for processing a whole wafer comprising:
at least a first flowcell and a second flowcell, each flowcell having a wafer and body sandwiching a gasket;
a cassette retaining the flowcells in a predetermined orientation; and
a fluidic station comprising:
a first selector valve having one port coupled to the first flowcell and a second port coupled to the second flowcell;
a first collector valve selectively coupled to the first flowcell through the first selector valve;
a second collector valve selectively coupled to the second flowcell through the first selector valve;
at least one valve adapted to selectively open a common fluid path to first collector valve and the second collector valve; and
a pump for delivering fluid through the first selector valve

64. The apparatus of claim 63, further comprising:
a third flowcell and a fourth flowcell retain by the cassette, each flowcell having a wafer and body sandwiching a gasket;

64. The apparatus of claim 63, wherein the fluidic station further comprises:
a second selector valve having one port coupled to the third flowcell and a second port coupled to the fourth flowcell;
a third collector valve selectively coupled to the third flowcell through the second selector valve and having a port coupled to the common fluid path;
a fourth collector valve selectively coupled to the fourth flowcell through the second selector valve and having a port coupled to the common fluid path; and
at least one valve adapted to selectively open a common fluid path to first collector valve and the second collector valve.

65. The apparatus of claim 64, wherein the pump drives fluid through the second selector valve.

66. The apparatus of claim 64, wherein the pump drives fluid through the all the flowcells simultaneously.

67. The apparatus of claim 63, wherein the first selector valve has a first state that provides a first re-circulating flow path through the pump and the first flowcell and a second re-circulating flow path through the pump and the second flowcell.

68. The apparatus of claim 63, where the each collector valve further comprises:
a common port coupled to the coupled to selector valve, a first port coupled to a recovery line, and a second port coupled to the at least one valve adapted to selectively open the fluid path to the first selector valve.

69. The apparatus of claim 63, further comprising a cradle adapted to retain the cassette in a predetermined orientation.

70. A method for processing whole wafers comprising:
providing a first flowcell comprising a gasket and a body;
compressing the gasket between a whole wafer and the body to define a processing region of the first flowcell;
selectively flowing fluids into the processing region.

71. The method of claim 70, wherein the step of selectively flowing fluids into the processing region further comprises:
re-circulating fluid through the first flowcell.

72. The method of claim 70 further comprising:
retaining the first flowcell and at least a second flowcell in a cassette in a predetermined orientation.

73. The method of claim 72, wherein the step of selectively flowing fluids into the processing region further comprises:
re-circulating fluid through a plurality of flowcells with a single pump.

74. The method of claim 73, wherein the step of re-circulating fluid further comprises:
setting a first selector valve to a state that provides a two re-circulating flowpaths respectively through the first flowcell and the second flowcell; and
setting a second selector valve to a state that provides a two re-circulating flowpaths respectively through at least a third flowcell.

75. The method of claim 74, wherein the step of re-circulating fluid further comprises:
driving a fluid through the first through third flowcell with a single pump.

76. The method of claim 72 further comprising:
rotating the cassette.

77. The method of claim 76 further comprising:
replacing the cassette with a second cassette having flowcells to the processed disposed therein.
